(19) United States
(12) Patent Application Publication
(10) Pub. No.: US 2016/0203353 A1
(43) Pub. Date: Jul. 14, 2016

(54) ELECTRONIC DEVICE

(71) Applicant: Innolux Corporation, Chu-Nan (TW)

(72) Inventors: I-Che LEE, Chu-Nan (TW); Chen-Chia HSU, Chu-Nan (TW); Yi-Ming CHOU, Chu-Nan (TW); Yu-Tsung LIU, Chu-Nan (TW); Te-Yu LEE, Chu-Nan (TW)

(73) Assignee: Innolux Corporation, Chu-Nan (TW)

(21) Appl. No.: 14/970,460

(22) Filed: Dec. 15, 2015

(30) Foreign Application Priority Data
Jan. 9, 2015 (TW) 104100701

(51) Int. Cl. G06K 9/00; H01L 29/16; H01L 27/12; H01L 29/786; H01L 29/868; H01L 29/24; H01L 29/04

(52) U.S. Cl. CPC G06K 9/0004; H01L 29/24; H01L 29/16; H01L 29/1604; H01L 29/04; H01L 29/78603; H01L 29/7869; H01L 29/78666; H01L 29/78675; H01L 29/868; H01L 27/1225; H01L 27/1222; H01L 27/1218

(57) ABSTRACT

An electronic device is provided. The electronic device includes a substrate, a first refractive layer, a second refractive layer and an electronic component. The first and the second refractive layers are stacked on the substrate, wherein the first refractive layer is disposed on the second refractive layer. The first refractive layer has a refractive index n₁₁ at a wavelength of visible light and a refractive index n₁₂ at a wavelength of UV light, and the second refractive layer has a refractive index n₂₁ at the wavelength of visible light and a refractive index n₂₂ at the wavelength of UV light. The electronic component includes a semiconductor layer disposed on the first refractive layer. The refractive indexes n₁₁, n₁₂, n₂₁, and n₂₂ satisfy the following equation: |n₂₂−n₂₁|>|n₁₂−n₁₁|.

This application claims the benefit of Taiwan application Serial No. 104100701, filed on Jan. 9, 2015, the subject matter of which is incorporated herein by reference.

### TECHNICAL FIELD

The disclosure relates in general to an electronic device, and more particularly to an electronic device including a semiconductor layer.

### BACKGROUND

Some electronic devices have various appearances which are not limited to a plane structure, and possess features such as lightweight, slimness, and impact resistance, and thus become a focus in the field of research and application. A type of substrate commonly used in such electronic devices is formed of polymer. However, if the substrate is formed of polymer, the manufacturing process of the electronic device may be restricted. For example, the method for manufacturing a semiconductor layer used in the electronic component includes forming a semiconductor layer at first, then radiating the semiconductor layer by using excimer laser. In this manufacturing process, if the intensity of the excimer laser is too strong, the substrate disposed underneath may be damaged. On the other hand, if the intensity of the excimer laser is insufficient, the film property of the semiconductor layer will be unsatisfactory.

### SUMMARY

This disclosure provides an electronic device having two refractive layers of different properties disposed between a semiconductor layer and a substrate for improving the quality of the semiconductor layer.

According to some embodiments, the electronic device includes a substrate, a first refractive layer, a second refractive layer and an electronic component. The first refractive layer and the second refractive layer are stacked on the substrate, wherein the first refractive layer is disposed on the second refractive layer. The first refractive layer has a refractive index n₁₁ at a wavelength of visible light and a refractive index n₁₂ at a wavelength of UV light, and the second refractive layer has a refractive index n₂₁ at the wavelength of visible light and a refractive index n₂₂ at the wavelength of UV light. The electronic component includes a semiconductor layer which is disposed on the first refractive layer. The refractive indexes n₁₁, n₁₂, n₂₁, and n₂₂ satisfy the following equation:

|n₂₂−n₂₁|>n₁₂−n₁₁|.

### BRIEF DESCRIPTION OF THE DRAWINGS

FIGS. 1A-1B are schematic diagrams of an electronic device according to one embodiment.

FIG. 2 is a schematic diagram of an electronic device according to another embodiment.

FIGS. 3-11 show the optical properties of different examples.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

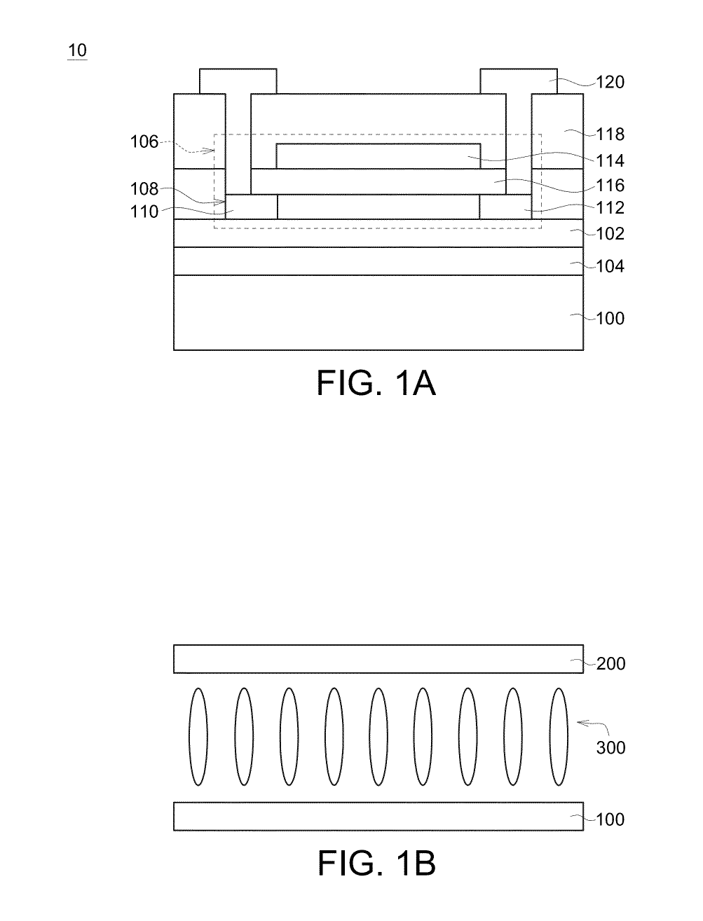

Referring to FIGS. 1A-1B, schematic diagrams of an electronic device 10 according to one embodiment are shown. The electronic device 10 includes a substrate 100, a first refractive layer 102, a second refractive layer 104, and an electronic component 106. The first refractive layer 102 and the second refractive layer 104 are stacked on the substrate 100, wherein the first refractive layer 102 is disposed on the second refractive layer 104. The first refractive layer 102 has a refractive index n₁₁ at a wavelength of visible light λ₁ and a refractive index n₁₂ at a wavelength of UV light λ₂, and the second refractive layer 104 has a refractive index n₂₁ at a wavelength of visible light λ₁ and a refractive index n₂₂ at the wavelength of UV light λ₂. The refractive indexes n₁₁, n₁₂, n₂₁, and n₂₂ satisfy the following equation:

|n₂₂−n₂₁|>|n₁₂−n₁₁|.

The electronic component 106 includes a semiconductor layer 108, and the semiconductor layer 108 is disposed on the first refractive layer 102.

Specifically, the electronic device 10 may be, for example, a display panel, as shown in FIG. 1B, in which some elements are omitted. Typically, as shown in FIG. 1B, the display panel further comprises a second substrate 200 and a display layer 300. The second substrate 200 is opposite to the substrate 100. The display layer 300 is disposed between the substrate 100 and the second substrate 200. And the display layer 300 may be a liquid crystal layer as shown in FIG. 1B, or other material such as organic light emitting diode or inorganic light emitting diode.

Referring back to FIG. 1A, the substrate 100 may be formed of a hard inorganic material permeable to the light such as glass, quartz, or the like, or a hard inorganic material impermeable to the light such as wafer, ceramics or the like, or formed of a flexible organic material such as plastics, rubber, polyimide (PI) or polyethylene terephthalate (PET). In particular, the substrate may be a flexible substrate formed of polyimide (PI) or polyethylene terephthalate (PET).

The electronic component 106 is a thin film transistor. The method for manufacturing the thin film transistor includes following steps. Firstly, a semiconductor layer 108 is formed on the first refractive layer 102. Then, the semiconductor layer 108 is radiated by an excimer laser using UV light. The substrate 100 will be damaged if the intensity of the UV light is too strong, but the film property of the semiconductor layer 108 will be unsatisfactory if the intensity of the UV light is too weak. Therefore, in each embodiment of the present disclosure, at least a first refractive layer 102 and a second refractive layer 104 are disposed under the semiconductor layer 108 for effectively reflecting the UV light such that the semiconductor layer 108 disposed on the first refractive layer 102 and the second refractive layer 104 can absorb the UV light again. Therefore, in each embodiment of the present disclosure, while the intensity of the UV light does not damage the substrate 100, the semiconductor layer 108 can achieve excellent film property. In order to provide the electronic device 10 with better transparency, the first refractive layer 102 and the second refractive layer 104 preferably have an excellent transmittance for visible light. The above effects can be achieved through the adjustment of the values of n₁₁, n₁₂, n₂₁ and n₂₂. In each embodiment of the present disclosure, the semiconductor layer 108 may be formed of amorphous silicon, poly-crystalline silicon, indium gallium zinc oxide, or other metal oxides.

Remaining steps of the manufacturing method of the thin film transistor are disclosed below. A dielectric layer 116 is formed on the semiconductor layer 108, and a gate 114 corresponding to the semiconductor layer 108 is formed on the dielectric layer 116. Then, an insulating layer 118 is formed on the gate 114, and at least two contact holes penetrating the insulating layer 118 and the dielectric layer 116 are formed. The conductors 120 are filled into the contact holes for electrically connecting the drain region 110 and the source region 112 of the semiconductor layer 108 to form corresponding drain and source. Through the above steps, the thin film transistor can be formed on the first refractive layer 102.

According to some embodiments, the refractive indexes n₁₁, n₁₂, n₂₁, and n₂₂ further satisfy the following equations:

|(n₁₂−n₁₁)/n₁₂|×100%≦3%, and

|(n₂₂−n₂₁)/n₂₂|×100%≧5%.

According to some embodiments, the refractive index n₂₂ is greater than the refractive index n₁₂. In some embodiments, each of the first refractive layer 102 and the second refractive layer 104 is formed of silicon oxide (SiOₓ), silicon nitride (SiNₓ), silicon oxynitride (SiOₓN_{y}), hydrogen-doped silicon oxide (SiOₓ:H), hydrogen-doped silicon nitride (SiNₓ:H), germanium oxide (GeOₓ), germanium nitride (GeNₓ), hafnium oxide (HfOₓ), hafnium nitride (HfNₓ), alumina (AlOₓ), organic material or the like. Through the adjustment of the process parameters for forming the first refractive layer 102 and the second refractive layer 104, the values of n₁₁, n₁₂, n₂₁ and n₂₂ are conformed to the characteristics described above. In some embodiments, a composite layer comprising the stacked first and the second refractive layers 102 and 104 has an average transmittance greater than 80% for the incident light having a wavelength of 400 to 700 nm and an average reflectivity greater than 60% for the incident light having a wavelength of 300 to 350 nm.

For example, in some embodiments, the wavelength of visible light λ₁ is 550 nm, and the wavelength of UV light λ₂ is 308 nm. Here, according to one embodiment, n₁₁ is between 0.74 and 2.21, n₁₂ is between 0.75 and 2.25, n₂₁ is between 0.73 and 2.18, and n₂₂ is between 5.00 and 15.00. According to a preferred embodiment, n₁₁ is between 1.32 and 1.62, n₁₂ is between 1.35 and 1.65, n₂₁ is between 1.31 and 1.60, and n₂₂ is between 9.00 and 11.00. According to an even preferred embodiment, n₁₁=1.47, n₁₂=1.50, n₂₁=1.45, and n₂₂=10.00. According to one embodiment, the first refractive layer 102 has a thickness of 51.6 to 154.9 nm, and the second refractive layer 104 has a thickness of 88.5 to 265.6 nm. According to a preferred embodiment, the first refractive layer 102 has a thickness of 93.3 to 113.3 nm, and the second refractive layer 104 has a thickness of 167.1 to 187.1 nm. According to an even preferred embodiment, the first refractive layer 102 has a thickness of 103.3 nm, and the second refractive layer 104 has a thickness of 177.1 nm.

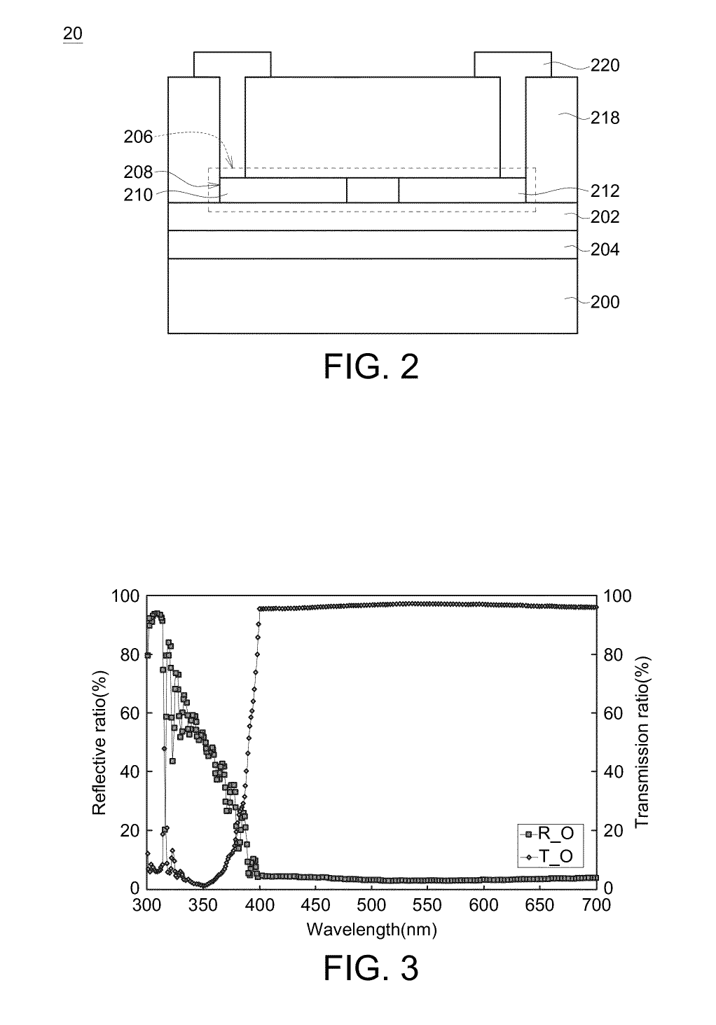

Referring to FIG. 2, a schematic diagram of an electronic device 20 according to another embodiment is shown. The electronic device 20 includes a substrate 200, a first refractive layer 202, a second refractive layer 204 and an electronic component 206. The first refractive layer 202 and the second refractive layer 204 are stacked on the substrate 200, wherein the first refractive layer 202 is disposed on the second refractive layer 204. The first refractive layer 202 has a refractive index n₁₁ at a wavelength of visible light λ₁ and a refractive index n₁₂ at a wavelength of UV light λ₂, the second refractive layer 204 has a refractive index n₂₁ at the wavelength of visible light λ₁ and a refractive index n₂₂ at the wavelength of UV light λ₂. The refractive indexes n₁₁, n₁₂, n₂₁, and n₂₂ satisfy the following equation:

|n₂₂−n₂₁|>|n₁₂−n₁₁|.

The electronic component 206 includes a semiconductor layer 208, and the semiconductor layer 208 is disposed on the first refractive layer 202.

Specifically, the electronic device 20 may be, for example, a fingerprint identification device. The substrate 100 may be formed of a hard inorganic material permeable to the light such as glass, quartz, or the like, or a hard inorganic material impermeable to the light such as wafer, ceramics or the like, or formed of a flexible organic material such as plastics, rubber, polyimide (PI) or polyethylene terephthalate (PET). The electronic component 206 is a diode, includes a P+ doped region 210 and an N+ doped region 212, and is formed by doping the semiconductor layer 208. The electronic device 20 further includes an insulating layer 218 and conductors 220 connecting the P+ doped region 210 and the N+ doped region 212 through at least two contact holes. The semiconductor layer 208 may be formed of amorphous silicon, poly-crystalline silicon, indium gallium zinc oxide, or other metal oxides.

The characteristics of the first refractive layer 202 and the second refractive layer 204 are the same as that of the first refractive layer 102 and the second refractive layer 104, and are not repeated here.

In the above disclosure, the electronic device is exemplified by a display panel including a thin film transistor and a fingerprint identification device including diode, but the electronic device of the disclosure is not limited thereto. For example, the electronic device of the disclosure may be a flexible electronic device, a biomedical device, a mobile phone, a notebook computer, a tablet PC, an identity card, a credit card, an electronic key, or the like. Any electronic devices including a semiconductor layer (such as a poly-crystalline silicon layer) disposed on the substrate are within the spirit of the disclosure. Moreover, the application of the disclosure is not limited to the electronic device formed by using the excimer laser process. The disclosure is applicable to any electronic devices whose manufacturing process uses the radiation of the UV light.

The optical effects that can be achieved by the first refractive layer and the second refractive layer are disclosed below in a number of embodiments in which the first refractive layer has a refractive index n₁₁ at a wavelength of visible light 550 nm and a refractive index n₁₂ at a wavelength of UV light 308 nm, and the second refractive layer has a refractive index n₂₁ at a wavelength of visible light 550 nm and a refractive index n₂₂ at the wavelength of UV light 308 nm. The wave range of visible light is between 400 nm and 700 nm, and the wave range of UV light is between 300 nm and 350 nm.

Referring to FIG. 3, in the first embodiment, n₁₁=1.47, n₁₂=1.50, n₂₁=1.45, and n₂₂=10.00. The first refractive layer has a thickness of 103.3 nm, and the second refractive layer has a thickness of 177.1 nm. The drawing shows that in the wave range of UV light, the two refractive layers as a whole have an average reflectivity greater than 60% (see the R_O curve), hence conforming to process requirements. In the wave range of visible light, the two refractive layers as a whole have an average transmittance greater than 80% (see the T_O curve), hence conforming to the requirement of transparency.

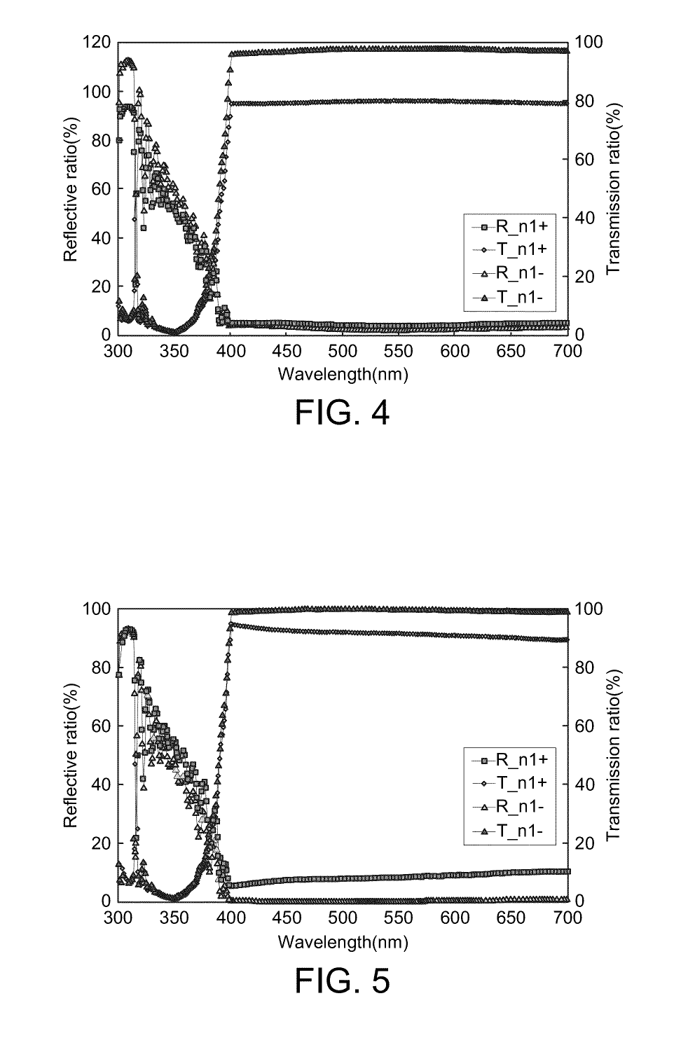

Referring to FIG. 4, the second embodiment includes two groups of data. In comparison to the first embodiment, the refractive index of the first refractive layer is changed, while the refractive index of the second refractive layer remains unchanged. In the first group, the refractive index of the first refractive layer is increased by 10%. At this time, n₁₁ and n₁₂ are 1.62 and 1.65 (see the R_n1+ and T_n1+ curves), respectively. In the second group, the refractive index of the first refractive layer is reduced by 10%. At this time, n₁₁ and n₁₂ are 1.32 and 1.35 (see the R_n1− and T_n1− curves), respectively. In the two groups of data, n₂₁=1.45, and n₂₂=10.00. The first refractive layer has a thickness of 103.3 nm, and the second refractive layer has a thickness of 177.1 nm. The drawing shows that in the wave range of UV light, the two refractive layers as a whole have an average reflectivity greater than 60% (see the R_n1+ and R_n1− curves), hence conforming to process requirements. In the wave range of visible light, the two refractive layers as a whole have an average transmittance greater than 80% (see the T_n1+ and T_n1− curves), hence conforming to the requirement of transparency.

Referring to FIG. 5, the third embodiment includes two groups of data. In comparison to the first embodiment, the refractive index of the first refractive layer is further changed, while the refractive index of the second refractive layer remains unchanged. In the first group, the refractive index of the first refractive layer is increased by 50%. At this time, n₁₁ and n₁₂ are 2.21 and 2.25 (see the R_n1+ and T_n1+ curves), respectively. In the second group, the refractive index of the first refractive layer is reduced by 50%. At this time, n₁₁ and n₁₂ are 0.74 and 0.75 (see the R_n1− and T_n1− curves), respectively. In the two groups of data, n₂₁=1.45, and n₂₂=10.00. The first refractive layer has a thickness of 103.3 nm, and the second refractive layer has a thickness of 177.1 nm. The drawing shows that in the wave range of UV light, the two refractive layers as a whole have an average reflectivity greater than 60% (see the R_n1+ and R_n1− curves), hence conforming to process requirements. In the wave range of visible light, the two refractive layers as a whole have an average transmittance greater than 80% (see the T_n1+ and T_n1− curves), hence conforming to the requirement of transparency.

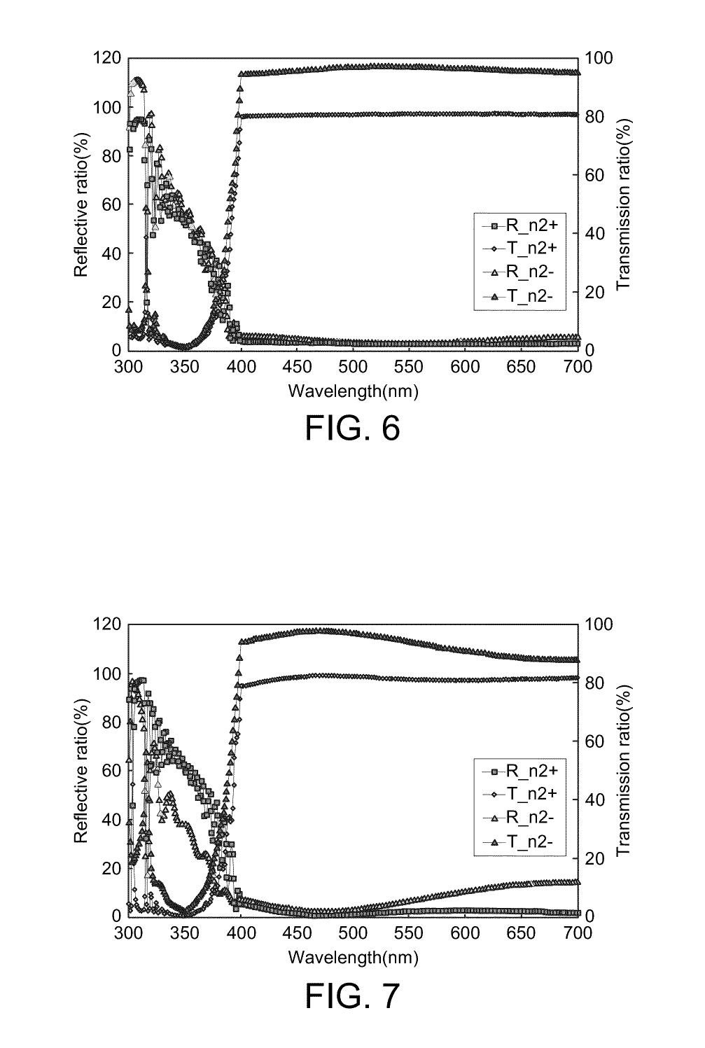

Referring to FIG. 6, the fourth embodiment includes two groups of data. In comparison to the first embodiment, the refractive index of the second refractive layer is changed, while the refractive index of the first refractive layer remains unchanged. In the first group, the refractive index of the second refractive layer is increased by 10%. At this time, n₂₁ and n₂₂ are 1.60 and 11.00 (see the R_n2+ and T_n2+ curves), respectively. In the second group, the refractive index of the second refractive layer is reduced by 10%. At this time, n₂₁ and n₂₂ are 1.31 and 9.00 (see the R_n2− and T_n2− curves), respectively. In the two groups of data, n₁₁=1.47, and n₁₂=1.5, the first refractive layer has a thickness of 103.3 nm, and the second refractive layer has a thickness of 177.1 nm. The drawing shows that in the wave range of UV light, the two refractive layers as a whole have an average reflectivity greater than 60% (see the R_n2+ and R_n2− curves), hence conforming to process requirements. In the wave range of visible light, the two refractive layers as a whole have an average transmittance greater than 80% (see the T_n2+ and T_n2− curves), hence conforming to the requirement of transparency.

Referring to FIG. 7, the fifth embodiment includes two groups of data. In comparison to the first embodiment, the refractive index of the second refractive layer is further changed, while the refractive index of the first refractive layer remains unchanged. In the first group, the refractive index of the second refractive layer is increased by 50%. At this time, n₂₁ and n₂₂ are 2.18 and 15.00 (see the R_n2+ and T_n2+ curves), respectively. In the second group, the refractive index of the second refractive layer is reduced by 50%. At this time, n₂₁ and n₂₂ are 0.73 and 5.00 (see the R_n2− and T_n2− curves), respectively. In the two groups of data, n₁₁=1.47, and n₁₂=1.50, the first refractive layer has a thickness of 103.3 nm, and the second refractive layer has a thickness of 177.1 nm. The drawing shows that in the wave range of UV light, the two refractive layers as a whole have an average reflectivity greater than 60% (see the R_n2+ and R_n2− curves), hence conforming to process requirements. In the wave range of visible light, the two refractive layers as a whole have an average transmittance greater than 80% (see the T_n2+ and T_n2− curves), hence conforming to the requirement of transparency.

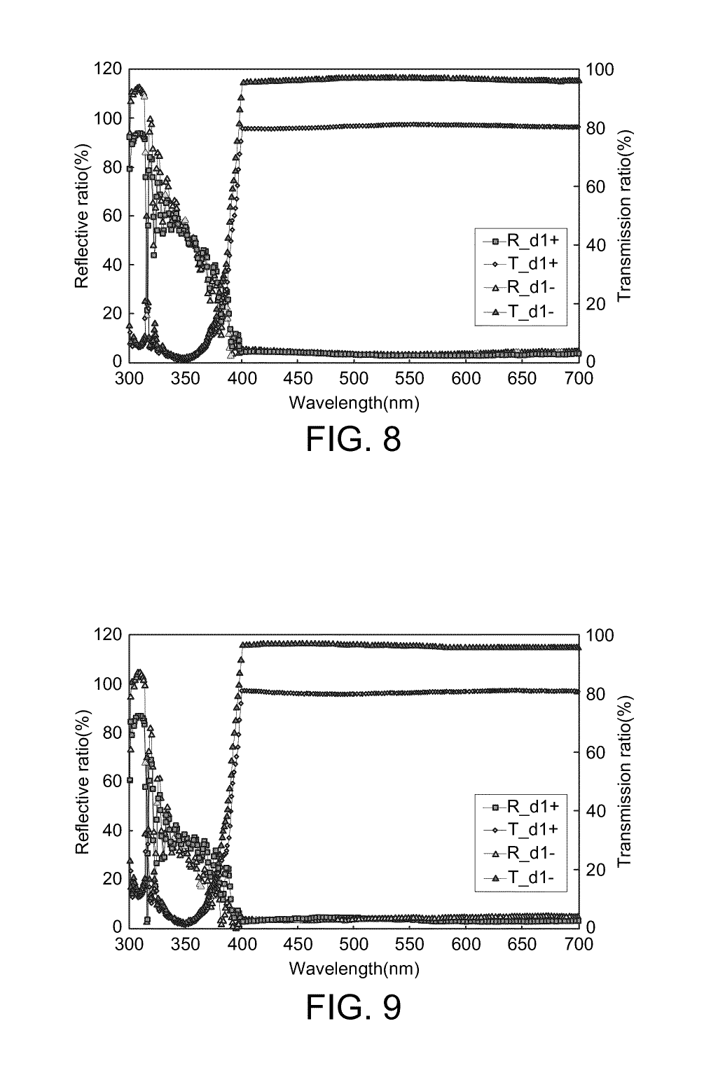

Referring to FIG. 8, the sixth embodiment includes two groups of data. In comparison to the first embodiment, the thickness of the first refractive layer is changed, while the thickness of the second refractive layer remains unchanged. In the first group, the thickness of the first refractive layer is increased by 10 nm. At this time, the first refractive layer has a thickness of 113.3 nm (see the R_d1+ and T_d1+ curves). In the second group, the thickness of the first refractive layer is reduced by 10 nm. At this time, the first refractive layer has a thickness of 93.3 nm (see the R_d1− and T_d1− curves). In the two groups of data, n₁₁=1.47, n₁₂=1.50, n₂₁=1.45, n₂₂=10.00, and the second refractive layer has a thickness of 177.1 nm. The drawing shows that in the wave range of UV light, the two refractive layers as a whole have an average reflectivity greater than 60% (see the R_d1+ and R_d1− curves), hence conforming to process requirements. In the wave range of visible light, the two refractive layers as a whole have an average transmittance greater than 80% (see the T_d1+ and T_d1− curves), hence conforming to the requirement of transparency.

Referring to FIG. 9, the seventh embodiment includes two groups of data. In comparison to the first embodiment, the thickness of the first refractive layer is further changed, while the thickness of the second refractive layer remains unchanged. In the first group, the thickness of the first refractive layer is increased by 50%. At this time, the first refractive layer has a thickness of 154.9 nm (see the R_d1+ and T_d1+ curves). In the second group, the thickness of the first refractive layer is reduced by 50%. At this time, the first refractive layer has a thickness of 51.6 nm (see the R_d1− and T_d1− curves). In the two groups of data, n₁₁=1.47, n₁₂=1.50, n₂₁=1.45, n₂₂10.00, and the second refractive layer has a thickness of 177.1 nm. The drawing shows that in the wave range of UV light, the two refractive layers as a whole have an average reflectivity greater than 60% (see the R_d1+ and R_d1− curves), hence conforming to process requirements. In the wave range of visible light, the two refractive layers as a whole have an average transmittance greater than 80% (see the T_d1+ and T_d1− curves), hence conforming to the requirement of transparency.

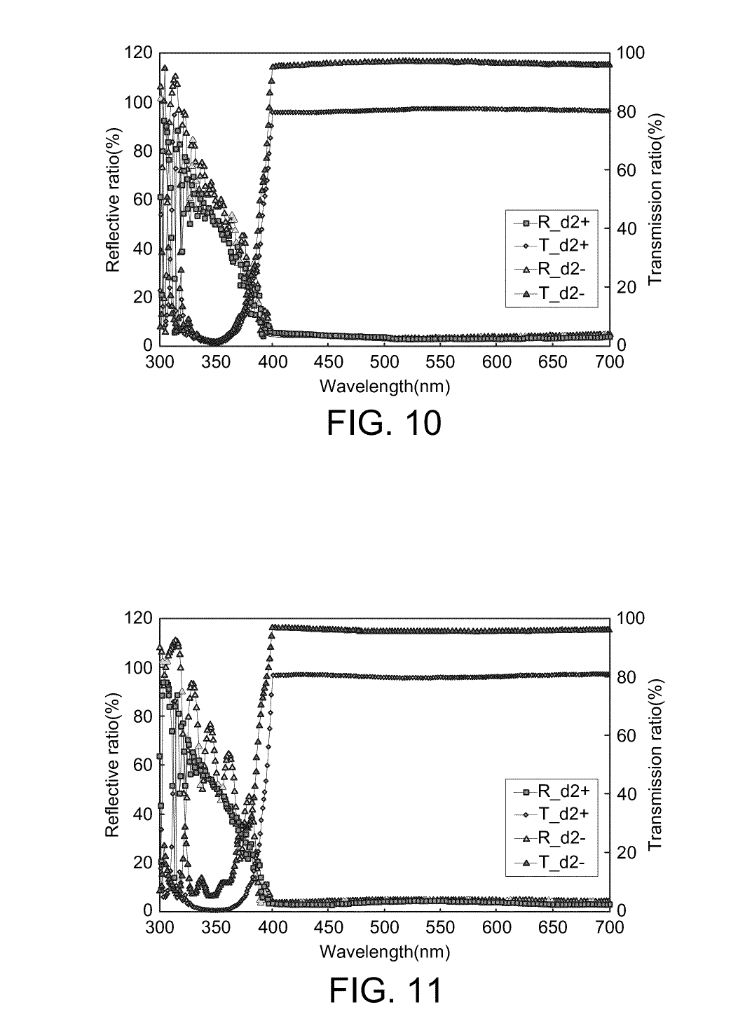

Referring to FIG. 10, the eighth embodiment includes two groups of data. In comparison to the first embodiment, the thickness of the second refractive layer is changed, while the thickness of the first refractive layer remains unchanged. In the first group, the thickness of the second refractive layer is increased by 10 nm. At this time, the second refractive layer has a thickness of 187.1 nm (see the R_d2+ and T_d2+ curves). In the second group, the thickness of the second refractive layer is reduced by 10 nm. At this time, the second refractive layer has a thickness of 167.1 nm (see the R_d2− and T_d2− curves). In the two groups of data, n₁₁=1.47, n₁₂=1.50, n₂₁=1.45, n₂₂=10.00, and the first refractive layer has a thickness of 103.3 nm. The drawing shows that in the wave range of UV light, the two refractive layers as a whole have an average reflectivity greater than 60% (see the R_d2+ and R_d2− curves), hence conforming to process requirements. In the wave range of visible light, the two refractive layers as a whole have an average transmittance greater than 80% (see the T_d2+ and T_d2− curves), hence conforming to the requirement of transparency.

Referring to FIG. 11, the ninth embodiment includes two groups of data. In comparison to the first embodiment, the thickness of the second refractive layer is further changed, while the thickness of the first refractive layer remains unchanged. In the first group, the thickness of the second refractive layer is increased by 50%. At this time, the second refractive layer has a thickness of 265.6 nm (see the R_d2+ and T_d2+ curves). In the second group, the thickness of the second refractive layer is reduced by 50%. At this time, the second refractive layer has a thickness of 88.5 nm (see the R_d2− and T_d2− curves). In the two groups of data, n₁₁=1.47, n₁₂=1.50, n₂₁=1.45, n₂₂=10.00, and the first refractive layer has a thickness of 103.3 nm. The drawing shows that in the wave range of UV light, the two refractive layers as a whole have an average reflectivity greater than 60% (see the R_d2+ and R_d2− curves), hence conforming to process requirements. In the wave range of visible light, the two refractive layers as a whole have an average transmittance greater than 80% (see the T_d2+ and T_d2− curves), hence conforming to the requirement of transparency.

Based on the embodiments exemplified above, it can be known that the substrate will not be damaged during the process of manufacturing the electronic component on the first refractive layer and the characteristics of the electronic component will satisfy the requirement of use as long as the refractive indexes of the first refractive layer the second refractive layer of the substrate (i.e. n₁₁, n₁₂, n₂₁ and n₂₂) satisfies the following equation:

|n₂₂−n₂₁|>|n₁₂−n₁₁|.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An electronic device, comprising:
a substrate;
a first refractive layer and a second refractive layer stacked on the substrate, wherein the first refractive layer is disposed on the second refractive layer, the first refractive layer has a refractive index n₁₁ at a wavelength of visible light and a refractive index n₁₂ at a wavelength of UV light, and the second refractive layer has a refractive index n₂₁ at the wavelength of visible light and a refractive index n₂₂ at the wavelength of UV light; and
an electronic component comprising a semiconductor layer disposed on the first refractive layer;
wherein the refractive indexes n₁₁, n₁₂, n₂₁, and n₂₂ satisfy the following equation:

|n₂₂−n₂₁|>|n₁₂−n₁₁|.

2. The electronic device according to claim 1, wherein the refractive indexes n₁₁, n₁₂, n₂₁, and n₂₂ further satisfy the following equations:

|(n₁₂−n₁₁)/n₁₂|×100%≦3%, and

|(n₂₂−n₂₁)/n₂₂|×100%≧5%.

3. The electronic device according to claim 2, wherein the wavelength of visible light is 550 nm, and the wavelength of UV light is 308 nm.

4. The electronic device according to claim 3, wherein the semiconductor layer is formed of amorphous silicon, poly-crystalline silicon, indium gallium zinc oxide, or other metal oxides.

5. The electronic device according to claim 1, wherein the refractive index n₂₂ is greater than the refractive index n₁₂.

6. The electronic device according to claim 1, wherein the first refractive layer and the second refractive layer are formed of silicon oxide (SiOₓ), silicon nitride (SiNₓ), silicon oxynitride (SiOₓN_{y}), hydrogen-doped silicon oxide (SiOₓ:H), hydrogen-doped silicon nitride (SiNₓ:H), germanium oxide (GeOₓ), germanium nitride (GeNₓ), hafnium oxide (HfOₓ), hafnium nitride (HfNₓ) or alumina (AlOₓ).

7. The electronic device according to claim 1, wherein the substrate is a flexible substrate formed of polyimide (PI) or polyethylene terephthalate (PET).

8. The electronic device according to claim 1, wherein a composite layer comprising the stacked first and second refractive layers has an average transmittance greater than 80% for an incident light having a wavelength of 400 to 700 nm and an average reflectivity greater than 60% for an incident light having a wavelength of 300 to 350 nm.

9. The electronic device according to claim 1, wherein the electronic component is a thin film transistor, and the electronic device is a display panel.

10. The electronic device according to claim 9, further comprising: a second substrate opposite to the substrate; and a display layer disposed between the substrate and the second substrate.

11. The electronic device according to claim 1, wherein the electronic component is a diode, and the electronic device is a fingerprint identification device.
